(19) United States
(12) Patent Application Publication
(10) Pub. No.: US 2024/0425951 A1
(43) Pub. Date: Dec. 26, 2024

(54) RECYCLED ALUMINUM COMPOSITION FOR COMPUTER CHASSIS

(71) Applicant: DELL PRODUCTS L.P., Round Rock, TX (US)

(72) Inventors: Nicholas Abbatiello, Round Rock, TX (US); Allison Ward, Northville, MI (US); XinHua Tian, Shanghai (CN)

(73) Assignee: DELL PRODUCTS L.P., Round Rock, TX (US)

(21) Appl. No.: 18/213,400

(22) Filed: Jun. 23, 2023

(51) Int. Cl. C22C 21/08; G06F 1/16; H05K 5/04

(52) U.S. Cl. CPC C22C 21/08; G06F 1/1633; H05K 5/04

(57) ABSTRACT

Recycled aluminum compositions, methods of making the compositions, and products containing the compositions are described. The recycled aluminum compositions can contain 10 wt. % to 90 wt. % low carbon aluminum; 10 wt. % to 90 wt. % of pre-consumer recycled aluminum 6063; and up to 10 wt. % of post-consumer recycled aluminum. Products containing the recycled aluminum compositions may, in some instances, have a total recycled aluminum content of 50 wt. % to 90 wt. %.

### BACKGROUND OF THE INVENTION

### A. Field of the Invention

The invention generally relates to a low carbon recycled aluminum compositions and method of producing the same with renewable energy source for use in articles of manufacture. For example, the low carbon recycled aluminum compositions can be used in the computer industry (e.g., chassis) and can allow for a more sustainable product (e.g., desktop, laptop, or mobile device computers).

### B. Description of Related Art

Aluminum has become a widely used metal, both for its availability and for its mechanical characteristics. Aluminum alloys are used in electronic and electrical devices such as computers, notebooks, laptops, cell phone, personal computers, e-books, and tablet personal computers, due to their good mechanical properties. However, its cost of transformation in the primary production process is very high, especially in relation to the energy used. Due at least in part to this, recycling processes are gaining ground with an environmental as well as an economic preference. Aluminum recycling, has grown in recent decades and the recycling processes are being treated as ways to replace raw materials in the development of products.

Generally mechanical properties and surface quality is sacrificed as recycled aluminum content is increased in a product, but using recycled aluminum reduces carbon emissions of the manufacturing process as compared to non-recycled aluminum. For example, the carbon emission of primary aluminum ingot production can be high if coal is the primary energy source. Recycled aluminum can also introduce more impurities into the final product, which can change the chemical composition and performance of the aluminum. Thus, limitations on the amount of recycled aluminum may be needed to avoid reduction of important performance requirements of the aluminum. Currently, either low carbon aluminum or recycled aluminum is generally used, which does not both maximize carbon emission reduction and material performance at the same time.

### SUMMARY OF THE INVENTION

A solution to at least some of the aforementioned problems is disclosed herein. In one aspect, the solution can include combining a mixture of low carbon primary aluminum, pre-consumer recycled aluminum 6063, and/or post-consumer recycled aluminum ingredients to achieve a required performance, maximize recycled content, and minimize carbon emission in the process of making the combined aluminum. The balance of these ingredients can be adjusted to obtain specific requirements for different consumer or commercial products. This may result in an article of manufacture (e.g., chassis for desktops, laptops, or mobile devices) that has a high overall content of recycled material without detrimentally comprising the mechanical strength of the resulting article of manufacture. In one aspect, it was found that a composition containing particular amounts of primary aluminum generated from a renewable energy source, pre-consumer recycled aluminum 6063, and/or post-consumer recycled aluminum can have excellent mechanical properties with minimum or acceptable impurity concentrations. Therefore, articles of manufacture made from such compositions can be more sustainable and/or less caustic to the environment.

One aspect of the present invention is directed to a recycled aluminum composition. The recycled aluminum composition can contain pre-consumer recycled aluminum 6063 and a low carbon primary aluminum produced by utilizing renewable energy source, and optionally post-consumer recycled aluminum. In certain aspects, the recycled aluminum composition may contain 10 wt. % to 90 wt. % of the low carbon primary aluminum generated from a renewable energy source, 10 wt. % to 90 wt. % of the pre-consumer recycled aluminum 6063, and up to 10 wt. % of the post-consumer recycled aluminum. In certain aspects, the recycled aluminum composition may contain 20 wt. % to 30 wt. % of the low carbon primary aluminum and 70 wt. % to 80 wt. % of the pre-consumer recycled aluminum 6063. In some aspects, the recycled aluminum composition may include at least 5% low carbon primary aluminum content. The recycled aluminum composition may include at least any one of, at most any one of, equal to any one of, or between any two of 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, or 100% low carbon primary aluminum content. In some aspects, the recycled aluminum composition may include at least 5% pre-consumer recycled aluminum 6063 content. The recycled aluminum composition may include at least any one of, at most any one of, equal to any one of, or between any two of 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, or 100% pre-consumer recycled aluminum 6063 content. In some aspects, the recycled aluminum composition may include up to 10% post-consumer recycled aluminum content. The recycled aluminum composition may include at least any one of, at most any one of, equal to any one of, or between any two of 0, 0.1, 1, 2, 3, 4, 5, 6, 7, 8, 9, 10, 11, 12, 13, 14, or 15% post-consumer recycled aluminum content. In some instances, the recycled aluminum composition is essentially free of post-consumer recycled aluminum content. The post-consumer recycled aluminum can contain, at least in part aluminum obtained from a post-industrial recycled source. In some aspects, low carbon primary aluminum can be produced, at least in part, by including a renewable hydro energy source. In some aspects, any of the renewable energy sources such as solar, wind, hydro, tidal, geothermal, and/or biomass energy sources are involved to generate the low carbon primary aluminum. In some aspects, pre-consumer recycled aluminum 6063 content may be obtained from recycled 6063-aluminum alloy, and in some instances from recycled 6063-aluminum alloy alone. In some aspects, pre-consumer recycled aluminum may comprise at least one of 5052-aluminum alloy, 6061-aluminum alloy, and/or 6063-aluminum alloy.

In some aspects, the recycled aluminum composition has a tensile strength at break equal to or greater than 205 MPa at 23° C., as measured in accordance with ASTM B557. In some aspects, the recycled aluminum composition has a tensile strength at break equal to any one of, greater than any one of, at most any one of, or between any two of 205 MPa, or 210 MPa, or 215 MPa, or 220 MPa, or 225 MPa, or 230 MPa, or 235 MPa, or 240 MPa, or 245 MPa, or 250 MPa at 23° C., as measured in accordance with ASTM B557 In some aspects, the recycled aluminum composition has a yield strength equal to or greater than 170 MPa at 23° C., as measured in accordance with ASTM B557. In some aspects, recycled aluminum composition has a yield strength equal to any one of, greater than any one of, at most any one of, or between any two of 170 MPa, 175 MPa, or 180 MPa, or 185 MPa, or 190 MPa, or 195 MPa, or 200 MPa, or 205 MPa, or 210 MPa, or 215 MPa, or 220 MPa at 23° C., as measured in accordance with ASTM B557 In some aspects, the recycled aluminum composition has an elongation at break equal to or greater than 8% at 23° C., as measured in accordance with ASTM B557/min. In some aspects, the recycled aluminum composition has an elongation at break equal to any one of, greater than any one of, at most any one of, or between any two of 8%, or 9%, or 10%, or 11%, or 12%, or 13%, or 14%, or 15%, or 20%, or 25%, or 30%, or 40%, or 50% at 23° C., as measured in accordance with ASTM B557/min.

In some aspects, the recycled aluminum composition contains at least 0.2 wt. % of silicon and no more than 0.35 wt. % of silicon. In some aspects, the recycled aluminum composition contains at least any one of, at most any one of, equal to any one of, or between any two of 0.2 wt. %, or 0.25 wt. %, or 0.3 wt. %, or 0.35 wt. % of silicon. In some aspects, the recycled aluminum composition contains at least 0.45 wt. % of magnesium and no more than 0.9 wt. % of magnesium. In some aspects, the recycled aluminum composition contains at least any one of, at most any one of, equal to any one of, or between any two of 0.45 wt. %, or 0.5 wt. %, or 0.55 wt. %, or 0.6 wt. % or 0.65 wt. %, or 0.7 wt. %, or 0.75 wt. %, or 0.8 wt. %, or 0.85 wt. %, or 0.9 wt. % of magnesium. In some aspects, the recycled aluminum composition contains no more than 0.35 wt. % iron, no more than 0.1 wt. % manganese, no more than 0.1 wt. % chromium, no more than 0.1 wt. % copper, no more than 0.1 wt. % titanium, and/or no more than 0.1 wt. % zinc. In some aspects the recycled aluminum composition contains no more than 0.15 wt. % of elements other than aluminum, silicon, magnesium, manganese, chromium, copper, titanium, zinc, and iron. In some aspects, the recycled aluminum composition contains no more than any one of, equal to any one of, at least any one of, or between any two of 0.35 wt. %, or 0.30 wt. %, or 0.25 wt. %, or 0.20 wt. %, or 0.15 wt. %, or 0.1 wt. %, or 0.05 wt. %, or 0 wt. %. Iron. In some aspects, the recycled aluminum composition contains no more than any one of, equal to any one of, at least any one of, or between any two of 0.1 wt. %, or 0.075 wt. %, or 0.05 wt. %, or 0.025 wt. %, or 0 wt. % of manganese. In some aspects, the recycled aluminum composition contains no more than any one of, equal to any one of, at least any one of, or between any two of 0.1 wt. %, or 0.075 wt. %, or 0.05 wt. %, or 0.025 wt. %, or 0 wt. %, of chromium. In some aspects, the recycled aluminum composition contains no more than any one of, equal to any one of, at least any one of, or between any two of 0.1 wt. %, or 0.075 wt. %, or 0.05 wt. %, or 0.025 wt. %, or 0 wt. %, of copper. In some aspects, the recycled aluminum composition contains no more than any one of, equal to any one of, at least any one of, or between any two of 0.1 wt. %, or 0.075 wt. %, or 0.05 wt. %, or 0.025 wt. %, or 0 wt. % of titanium. In some aspects, the recycled aluminum composition contains no more than any one of, equal to any one of, at least any one of, or between any two of 0.1 wt. %, or 0.075 wt. %, or 0.05 wt. %, or 0.025 wt. %, or 0 wt. %, of zinc. In some aspects the recycled aluminum composition contains no more than any one of, equal to any one of, at least any one of, or between any two of 0.15 wt. %, or 0.125 wt. %, or 0.1 wt. %, or 0.075 wt. %, 0.05 wt. %, or 0.025 wt. %, or 0 wt. % of elements other than aluminum, silicon, magnesium, manganese, chromium, copper, titanium, zinc, and iron.

In some aspects, the recycled aluminum composition can be comprised in a ingot, layer, or a sheet. In some aspects, the recycled aluminum composition can be extruded, cast, rolled, and/or forged. In some aspects, the recycled aluminum composition can be comprised in an article of manufacture. In some aspects, the article can be computer part. The computer can be a desktop computer, laptop computer, notebook computer, computer monitor, computer periphery, cell phone, computer tablet, calculator or the like. In some aspects, the article of manufacture can be a computer chassis or chassis part, such as a desktop computer chassis or chassis part or a laptop computer chassis or chassis part or a monitor chassis or chassis part, and/or computer peripheral chassis or chassis part.

One aspect of the present invention is directed to a computer chassis, a monitor chassis, and/or computer peripheral chassis containing the recycled aluminum composition described herein. The chassis can be for a desktop computer, a laptop computer, a notebook computer, a monitor, a computer peripheral, or a mobile device (e.g., a cell phone, a computer tablet, a calculator or the like). In some aspects, the recycled aluminum content of the chassis or chassis part can be at least 10%. In some aspects, the recycled aluminum content of the chassis or chassis part can be at least any one of, at most any one of, equal to any one of, or between any two of 10%, or 15%, or 20%, or 25%, 30%, or 35%, or 40%, or 45%, or 50%, or 55%, or 60%, or 65%, or 70%, or 75%, or 80%, or 85%, or 90%, or 95% or 100%.

One aspect of the present invention is directed to a method of making a recycled aluminum composition described herein. The method can include combining a low carbon primary aluminum with a pre-consumer recycled aluminum 6063, and alloying the low carbon primary aluminum and pre-consumer recycled aluminum 6063 to form the recycled aluminum. The method may, in some instances, further include conversion and fabrication of the recycled aluminum.

Other embodiments of the invention are discussed throughout this application. Any embodiment discussed with respect to one aspect of the invention applies to other aspects of the invention as well and vice versa. Each embodiment described herein is understood to be embodiments of the invention that are applicable to other aspects of the invention. It is contemplated that any embodiment discussed herein can be implemented with respect to any method or composition of the invention, and vice versa. Furthermore, compositions the invention can be used to achieve methods of the invention.

The following includes definitions of various terms and phrases used throughout this specification.

As used herein low carbon aluminum or low carbon primary aluminum refers to aluminum that is produced by a process that uses electricity from low carbon sources, e.g., sources of electricity that produce less carbon dioxide as waste compared to conventional fossil fuel electricity production. Low carbon sources of electricity include, but are not limited to, wind, solar, hydro, tidal, or nuclear sources.

As used herein recycled content of a material refers to the wt. % of the material obtained from, made from, and/or recovered from waste. Unless mentioned otherwise the waste can be post-industrial or post-consumer waste. Post-consumer waste of a material is waste generated by a customer of a substrate containing the material. Post-industrial waste is waste generated during a production process of a product that has not yet been used in the consumer market.

Chassis as used herein refers to housing and/or casing component for a product and/or parts thereof, such as a computer, central processing unit (CPU), monitor, display of the monitor, input device such as keyboard, mouse and/or mouse pad, storage unit such as solid state drive, hard disk drive, graphics processing unit, random access memory, sound card, speakers, microphones, webcam, and/or motherboard.

The terms “about” or “approximately” are defined as being close to as understood by one of ordinary skill in the art. In one non-limiting embodiment, the terms are defined to be within 10%, preferably within 5%, more preferably within 1%, and most preferably within 0.5%.

The terms “wt. %,” “vol. %,” or “mol. %” refers to a weight percentage of a component, a volume percentage of a component, or molar percentage of a component, respectively, based on the total weight, the total volume of material, or total moles, that includes the component. In a non-limiting example, 10 grams of component in 100 grams of the material is 10 wt. % of component. The term “ppm” refer to parts per million by weight, based on the total weight, of material that includes the component.

The term “substantially” and its variations are defined to include ranges within 10%, within 5%, within 1%, or within 0.5%.

The terms “inhibiting” or “reducing” or “preventing” or “avoiding” or any variation of these terms, when used in the claims and/or the specification includes any measurable decrease or complete inhibition to achieve a desired result.

The term “effective,” as that term is used in the specification and/or claims, means adequate to accomplish a desired, expected, or intended result.

The use of the words “a” or “an” when used in conjunction with any of the terms “comprising,” “including,” “containing,” or “having” in the claims, or the specification, may mean “one,” but it is also consistent with the meaning of “one or more,” “at least one,” and “one or more than one.”

The phrase “and/or” means and or or. To illustrate, A, B, and/or C includes: A alone, B alone, C alone, a combination of A and B, a combination of A and C, a combination of B and C, or a combination of A, B, and C. In other words, “and/or” operates as an inclusive or.

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The recycled aluminum composition of the present invention can “comprise,” “consist(s) essentially of,” or “consist of” particular ingredients, components, compositions, etc. disclosed throughout the specification. In one aspect of the present invention, and with reference to the transitional phrase “consist(s) essentially of” or “consisting essentially of,” a basic and novel characteristic of the present invention can include the recycled aluminum compositions having (1) high recycled content and/or (2) high content of low carbon aluminum, and/or (3) high mechanical properties.

All publications mentioned herein are incorporated herein by reference to disclose and describe the methods and/or materials in connection with which the publications are cited.

Other objects, features and advantages of the present invention will become apparent from the following detailed description and examples. It should be understood, however, that the detailed description and examples, while indicating specific embodiments of the invention, are given by way of illustration only and are not meant to be limiting. Additionally, it is contemplated that changes and modifications within the spirit and scope of the invention will become apparent to those skilled in the art from this detailed description. In further embodiments, features from specific embodiments may be combined with features from other embodiments. For example, features from one embodiment may be combined with features from any of the other embodiments. In further embodiments, additional features may be added to the specific embodiments described herein.

### BRIEF DESCRIPTION OF THE DRAWINGS

Advantages of the present invention may become apparent to those skilled in the art with the benefit of the following detailed description and upon reference to the accompanying drawings. While the invention is susceptible to various modifications and alternative forms, specific embodiments thereof are shown by way of example in the drawings. The drawings may not be to scale.

FIG. 1 illustrates a schematic of various aluminum recycling methods.

FIG. 2 illustrates carbon emission patterns with different combinations of low carbon aluminum and recycled aluminum content.

### DETAILED DESCRIPTION OF THE INVENTION

A computer chassis or its associated information technology devices such as a computer chassis, monitor chassis, and/or computer peripheral chassis may include recycled aluminum. A solution is described herein to at least some of the problems that may be associated with increasing the recycled content of aluminum containing aluminum composition without detrimentally jeopardizing the mechanical properties and usability of the composition in an article of manufacture (e.g., a chassis for an electronic device). In one aspect of the present invention, the discovery can include a recycled aluminum composition containing 20 wt. % to 30 wt. % of low carbon primary aluminum. 70 wt. % to 80 wt. % of pre-consumer recycled aluminum 6063, and optionally up to 10% post-consumer recycled aluminum. In some instances, a product made of the recycled aluminum composition can have a total recycled content of 50 wt. % to 90 wt. %. The mechanical properties and other metal impurity levels of such compositions can be sufficient for use in articles of manufacture that may have substantial use and/or may be prone to dropping (e.g., a chassis for an electronic device). Notably, the high recycled and renewable content of the compositions of the present invention can lead to a more sustainable or “green” article of manufacture without comprising costs and/or mechanical strength.

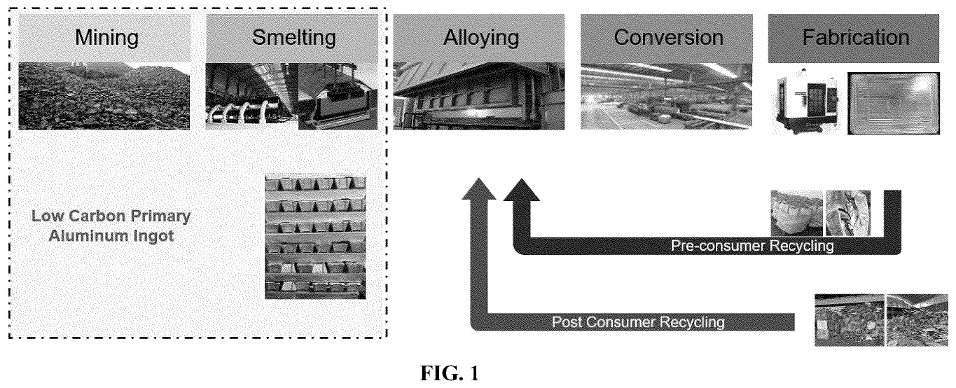

Referring to FIG. 1, a schematic of aluminum recycling methods are provided. Aluminum that is derived from primary or secondary sources can be used to form various articles of manufacture (e.g., consumer products, such as computer chassis), which after use can become waste. Primary aluminum sources include previously-unused aluminum, sometimes referred to as virgin aluminum, that is obtained from refinement of aluminum-containing ores. Secondary aluminum sources include aluminum that has entered the economy but is no longer serving its initial purpose. The environmental benefits of employing recycling aluminum include conserving energy, landscapes, and natural resources, and reducing toxic and nontoxic waste streams.

In certain aspects, recycled content of aluminum and utilization of renewable energy for production of a composition is increased while maintaining the desired mechanical properties of the composition. In some instances, this is achieved by supplementing renewable energy assisted generated low carbon aluminum content with pre-consumer recycled aluminum 6063, and optionally post-consumer recycled aluminum.

As illustrated in a non-limiting manner in the Examples, recycled aluminum compositions of the present invention can have lower carbon emissions compared to a comparative composition without the recycled aluminum content.

These and other non-limiting aspects of the present invention are discussed in further detail in the following sections.

### A. Recycled Aluminum Compositions

The recycled aluminum composition can contain i) 0 wt. % to 90 wt. % or at least any one of, at most any one of, equal to any one of, or between any two of 0, 1, 5, 10, 15, 20, 25, 30, 35, 40, 45, 50, 55, 60, 65, 70, 75, 80, 85, and 90 wt. % of a low carbon primary aluminum; and ii) 10 wt. % to 100 wt. % or at least any one of, at most any one of, equal to any one of, or between any two of 10, 15, 20, 25, 30, 35, 40, 45, 50, 55, 60, 65, 70, 75, 80, 85, 90, 95, 97, 98, 99, and 100 wt. % of a pre-consumer recycled aluminum 6063. In certain aspects, the recycled aluminum composition can further comprise up to 10 wt. % or at least any one of, at most any one of, equal to any one of, or between any two of 0, 1, 2, 3, 4, 5, 6, 7, 8, 9, 10, 11, 12, 13, 14, and 15 wt. % of the post-consumer recycled aluminum.

In some particular aspects, low carbon primary aluminum can be produced, at least in part, by including a renewable hydro energy source. In some aspects, any of the renewable energy sources such as solar, wind, hydro, tidal, geothermal, and/or biomass energy sources are involved to generate low carbon primary aluminum. In some aspects, pre-consumer recycled aluminum 6063 content may be obtained from recycled 6063-aluminum alloy, such as from recycled 6063-aluminum alloy alone. In some aspects, pre-consumer recycled aluminum may comprise at least one of 5052-aluminum alloy, 6061-aluminum alloy, and/or 6063-aluminum alloy. In some aspects, the renewably sourced primary aluminum can include a combination of various aluminum grades.

In certain aspects, the recycled aluminum composition can further contain one or more additives. In some instances, the additives may include iron, silicon, manganese, chromium, copper, titanium, zinc, and/or magnesium.

In some aspects, the recycled aluminum composition contains at least 0.2 wt. % of silicon and no more than 0.35 wt. % of silicon. In some aspects, the recycled aluminum composition contains at least any one of, at most any one of, equal to any one of, or between any two of 0.2 wt. %, or 0.25 wt. %, or 0.3 wt. %, or 0.35 wt. % of silicon. In some aspects, the recycled aluminum composition contains at least 0.45 wt. % of magnesium and no more than 0.9 wt. % of magnesium. In some aspects, the recycled aluminum composition contains at least any one of, at most any one of, equal to any one of, or between any two of 0.45 wt. %, or 0.5 wt. %, or 0.55 wt. %, or 0.6 wt. % or 0.65 wt. %, or 0.7 wt. %, or 0.75 wt. %, or 0.8 wt. %, or 0.85 wt. %, or 0.9 wt. % of magnesium. In some aspects, the recycled aluminum composition contains no more than 0.35 wt. % iron, no more than 0.1 wt. % manganese, no more than 0.1 wt. % chromium, no more than 0.1 wt. % copper, no more than 0.1 wt. % titanium, and/or no more than 0.1 wt. % zinc. In some aspects the recycled aluminum composition contains no more than 0.15 wt. % of elements other than aluminum, silicon, magnesium, manganese, chromium, copper, titanium, zinc, and iron. In some aspects, the recycled aluminum composition contains no more than any one of, equal to any one of, at least any one of, or between any two of 0.35 wt. %, or 0.30 wt. %, or 0.25 wt. %, or 0.20 wt. %, or 0.15 wt. %, or 0.1 wt. %, or 0.05 wt. %, or 0 wt. %. Iron. In some aspects, the recycled aluminum composition contains no more than any one of, equal to any one of, at least any one of, or between any two of 0.1 wt. %, or 0.075 wt. %, or 0.05 wt. %, or 0.025 wt. %, or 0 wt. % of manganese. In some aspects, the recycled aluminum composition contains no more than any one of, equal to any one of, at least any one of, or between any two of 0.1 wt. %, or 0.075 wt. %, or 0.05 wt. %, or 0.025 wt. %, or 0 wt. %, of chromium. In some aspects, the recycled aluminum composition contains no more than any one of, equal to any one of, at least any one of, or between any two of 0.1 wt. %, or 0.075 wt. %, or 0.05 wt. %, or 0.025 wt. %, or 0 wt. %, of copper. In some aspects, the recycled aluminum composition contains no more than any one of, equal to any one of, at least any one of, or between any two of 0.1 wt. %, or 0.075 wt. %, or 0.05 wt. %, or 0.025 wt. %, or 0 wt. % of titanium. In some aspects, the recycled aluminum composition contains no more than any one of, equal to any one of, at least any one of, or between any two of 0.1 wt. %, or 0.075 wt. %, or 0.05 wt. %, or 0.025 wt. %, or 0 wt. %, of zinc. In some aspects the recycled aluminum composition contains no more than any one of, equal to any one of, at least any one of, or between any two of 0.15 wt. %, or 0.125 wt. %, or 0.1 wt. %, or 0.075 wt. %, 0.05 wt. %, or 0.025 wt. %, or 0 wt. % of elements other than aluminum, silicon, magnesium, manganese, chromium, copper, titanium, zinc, and iron.

In some aspects, the recycled aluminum composition has a tensile strength at break equal to or greater than 205 MPa at 23° C., as measured in accordance with ASTM B557. In some aspects, the recycled aluminum composition has a tensile strength at break equal to any one of, greater than any one of, at most any one of, or between any two of 205 MPa, or 210 MPa, or 215 MPa, or 220 MPa, or 225 MPa, or 230 MPa, or 235 MPa, or 240 MPa, or 245 MPa, or 250 MPa at 23° C., as measured in accordance with ASTM B557 In some aspects, the recycled aluminum composition has a yield strength equal to or greater than 170 MPa at 23° C., as measured in accordance with ASTM B557. In some aspects, recycled aluminum composition has a yield strength equal to any one of, greater than any one of, at most any one of, or between any two of 170 MPa, 175 MPa, or 180 MPa, or 185 MPa, or 190 MPa, or 195 MPa, or 200 MPa, or 205 MPa, or 210 MPa, or 215 MPa, or 220 MPa at 23° C., as measured in accordance with ASTM B557 In some aspects, the recycled aluminum composition has an elongation at break equal to or greater than 8% at 23° C., as measured in accordance with ASTM B557/min. In some aspects, the recycled aluminum composition has an elongation at break equal to any one of, greater than any one of, at most any one of, or between any two of 8%, or 9%, or 10%, or 11%, or 12%, or 13%, or 14%, or 15%, or 20%, or 25%, or 30%, or 40%, or 50% at 23° C., as measured in accordance with ASTM B557/min.

### B. Methods for Making the Recycled Aluminum Compositions

The recycled aluminum compositions of the present invention can be made by various methods known in the art such as extrusion, casting, rolling, or forging, or any combination thereof. For example the components, such as the primary aluminum, pre-consumer recycled aluminum 6063, and/or the optional post-consumer recycled aluminum can be combined together and then alloying to form the recycled aluminum composition.

Mixtures including any combination of the foregoing mentioned components may be subjected to multiple blending and forming steps if desirable. For example, the aluminum composition may first be extruded and formed into ingots. The ingots may then be fed into a molding machine where it may be formed into any desirable shape or product. In some aspects, the aluminum composition may be formed into sheets or strands and subjected to processes such as annealing, welding, or fusing to additional aluminum composition(s) or other compositions and/or parts, such as computer parts.

### C. Articles of Manufacture

The recycled aluminum composition of the present invention can be comprised in an article of manufacture. Aspects of the disclosure also relate to articles including the recycled aluminum composition described herein. In some aspects the article can be a film, a sheet, a molded article, a welded article, a filament, or a powder.

The article can be a consumer product. In some aspects, the article can be a computer part, monitor part, and/or a computer periphery part. The computer can be desktop computer, laptop computer, notebook computer, cell phone, computer tablet, calculator or the like. In some particular aspects, the article can be a chassis or chassis part, such as a desktop computer chassis, monitor chassis, and/or computer peripheral chassis. In some aspects, a single part of a chassis, or the entire chassis may comprises at least any one of, at most any one of, equal to any one of, or between any two of 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, or 100% % the recycled aluminum composition.

In some instances the laptop or a notebook computer can have a keyboard, a mouse pad, a screen/display, a top cover, a bottom cover, and/or a back cover. In some aspects, the chassis can include at least a portion of a top cover, bottom cover, and/or back cover, or any combination thereof or all thereof. The bottom cover can, in some instances, have space/holes for one or more ports (e.g. including but not limited to USB port(s), HDMI port(s), SD card port(s), VGA connector port(s), microphone and/or speaker port(s), laptop charger port(s), laptop lock slot(s) and/or Ethernet port(s)) configured to attach peripherals such as printers, scanners, storage drives, monitors, speakers, microphones, webcams, USB cables and/or drives, chargers, laptop locks, Ethernet cable and/or SD cards with the laptop. In some aspects, the top cover and/or the back cover can have one or more holes for one or more ports. The laptop or notebook computer can have central processing unit (CPU), storage unit, graphics processing unit, random access memory, sound card, speakers, webcam, microphone, motherboard and/or battery, in the space between the covers, and/or the space between the screen/display and back cover. In some aspects, the top cover, bottom cover, and/or back cover can contain an aluminum composition described herein. In some aspects, independently at least 70 wt. %, such as 70 wt. % to 100 wt. % of the top cover, bottom cover, and/or back cover can contain an aluminum composition described herein. Independently, at least 70 wt. %, such as 70 wt. % to 100 wt. % of the top cover, bottom cover, and/or back cover can be comprised of recyclable, low carbon, and/or renewable material, wherein the recyclable, low carbon, and/or renewable material may contain additives.

In some instances the desktop computer can have a monitor and a computer case. The monitor can have a display screen and a casing. In some aspects, the chassis can include at least a portion of the computer case or casing, or any combination thereof or all thereof. The computer case can house various computer hardware including but not limited to CPU, storage unit, graphics processing unit, random access memory, sound card, and/or motherboard. The computer case can have one or more holes/spaces to attach, e.g., via various ports, various computer hardware and peripherals such as media drives, e.g., CD drives, printers, scanners, storage drives, monitors, speakers, microphones, webcams, USB cables and/or drives, and/or chargers with the computer. In some aspects, the computer case and/or the casing can contain a recycled aluminum composition described herein. In some aspects, independently at least 70 wt. %, such as 70 wt. % to 100 wt. % of the computer case and/or the casing can contain a recycled aluminum composition described herein. Independently, at least 70 wt. %, such as 70 wt. % to 100 wt. % of the computer case and/or the casing can be comprised of recyclable, low carbon, and/or renewable material, wherein the recyclable, low carbon, and/or renewable material may contain additives.

In some instances the tablet computer or cell phone can contain a display screen and a back panel. In some aspects, the chassis can include at least a portion of the back panel. Various tablet computer or cell phone hardware can be housed in between the display and a back panel, such as including but not limited to processors, computer chips, cameras, microphone, speaker, and/or battery. In some aspects, the back panel can be a foldable panel. In some aspects, at least 70 wt. %, such as 70 wt. % to 100 wt. % of the back panel can contain a recycled aluminum composition described herein. At least 70 wt. %, such as 70 wt. % to 100 wt. % of the back panel can be comprised of recyclable and/or renewable material, wherein the recyclable and/or renewable material may contain additives.

In the context of the present invention, at least the following 20 aspects are described. Aspect 1 is directed to recycled aluminum composition comprising: 10 to 90 wt. % primary aluminum; and 10 to 90 wt. % pre-consumer recycled aluminum 6063. Aspect 2 is directed to the recycled aluminum composition of aspect 1, wherein the primary aluminum comprises low carbon primary aluminum. Aspect 3 is directed to the recycled aluminum composition of any one of aspects 1 or 2, further comprising post-consumer recycled aluminum. Aspect 4 is directed to the recycled aluminum composition of any one of aspects 1 to 3, comprising up to 10 wt. % of the post-consumer recycled aluminum. Aspect 5 is directed to the recycled aluminum composition of any one of aspects 1 to 4, comprising: 20 to 30 wt. % of the primary aluminum; and/or 70 to 80 wt. % of the pre-consumer recycled aluminum 6063. Aspect 6 is directed to the recycled aluminum composition of any one of aspects 1 to 5, wherein the recycled aluminum composition has: a tensile strength at break equal to or greater than 205 MPa at 23° C., as measured in accordance with ASTM B557; and/or a yield strength equal to or greater than 170 MPa at 23° C., as measured in accordance with ASTM B557; and/or an elongation at break equal to or greater than 8% at 23° C., as measured in accordance with ASTM B557. Aspect 7 is directed to the recycled aluminum composition of any one of aspects 1 to 6, wherein the composition comprises silicon and magnesium. Aspect 8 is directed to the recycled aluminum composition of any one of aspects 1 to 7, comprising 0.2 to 0.35 wt. % silicon and 0.45 to 0.9 wt. % magnesium. Aspect 9 is directed to the recycled aluminum composition of any one of aspects 1 to 8, comprising no more than 0.35 wt. % iron, no more than 0.1 wt. % manganese, no more than 0.1 wt. % chromium, no more than 0.1 wt. % copper, no more than 0.1 wt. % titanium and no more than 0.1 wt. % zinc. Aspect 10 is directed to the recycled aluminum composition of any one of aspects 1 to 9, wherein the composition comprises no more than 0.15 wt. % of elements other than aluminum, silicon, magnesium, iron, manganese, chromium, copper, titanium, and zinc. Aspect 11 is directed to the recycled aluminum composition of any one of aspects 1 to 10, wherein the composition is an extruded, cast, rolled, or forged composition. Aspect 12 is directed to a computer chassis comprising the recycled aluminum composition of any one of aspects 1 to 11. Aspect 13 is directed to the computer chassis of aspect 12, wherein the computer chassis is a desktop computer chassis, a laptop computer chassis, or a computer tablet chassis. Aspect 14 is directed to the computer chassis of any one of aspects 12 to 13, wherein at least 10 wt. % of the computer chassis comprises the recycled aluminum composition. Aspect 15 is directed to a method of making a computer chassis, the method comprising forming at least a portion of the computer chassis with the recycled aluminum composition of any one of aspects 1 to 11. Aspect 16 is directed to the method of aspect 15, wherein at least 70 wt. % of the single part of a computer chassis comprises the recycled aluminum composition. Aspect 17 is directed to the method of any one of aspects 15 to 16, wherein the recycled aluminum composition comprises: 20 to 30 wt. % of the primary aluminum; and/or 70 to 80 wt. % of the pre-consumer recycled aluminum 6063. Aspect 18 is directed to the method of any one of aspects 15 to 17, wherein the recycled aluminum composition further comprises post-consumer recycled aluminum. Aspect 19 is directed to a method of making a recycled aluminum of any one of aspects 1 to 18, the method comprising: combining a low carbon primary aluminum with a pre-consumer recycled aluminum 6063; and alloying the low carbon primary aluminum and pre-consumer recycled aluminum 6063 to form the recycled aluminum. Aspect 20 is directed to the method of aspect 19, further comprising conversion and fabrication of the recycled aluminum.

### D. EXAMPLES

The present invention will be described in greater detail by way of specific examples. The following examples are offered for illustrative purposes only, and are not intended to limit the invention in any manner. Those of skill in the art will readily recognize a variety of noncritical parameters which can be changed or modified to yield essentially the same results.

### 1. Example 1-A Recycled Aluminum Composition of the Present Invention

Table 1 provides a non-limiting example of a recycled aluminum composition of the present invention. One embodiment, containing 25 wt. % of primary low carbon aluminum (produced with hydro-power) and 75% pre-consumer recycled Aluminum 6063, was tested for elemental composition and mechanical properties. Results are shown in Table 1.

TABLE 1
Recycled aluminum composition

| Material | Low Carbon and Recycled Aluminum 6063 | | | | | | | | | | | |
|---|---|---|---|---|---|---|---|---|---|---|---|---|
| Preferred | | | | | | | | | | Other Elements | | |
| Composition | | Fe | Si | Mn | Cr | Cu | Ti | Zn | Mg | Each | Total | Al |
| | Min | — | 0.2 | — | — | — | — | — | 0.45 | — | — | Remainder |
| | Max | 0.35 | 0.6 | 0.1 | 0.1 | 0.1 | 0.1 | 0.1 | 0.9 | 0.05 | 0.15 | |

| | | | |
|---|---|---|---|
| Material | Tensile Strength | Yield Strength | Elongation |
| Property | ≥205 MPa | ≥170 MPa | ≥8% |
| Data | | | |

The recycled aluminum composition of present invention in Table 1 can be characterized, converted, and fabricated to form molded articles containing the recycled aluminum composition.

Mechanical properties of the recycled aluminum composition was tested using standard methods. The recycled aluminum composition of Table 1 had a tensile strength at break equal to or greater than 205 MPa at 23° C., as measured in accordance with ASTM B557; a yield strength equal to or greater than 170 MPa at 23° C., as measured in accordance with ASTM B557; and an elongation at break equal to or greater than 8% at 23° C., as measured in accordance with ASTM B557.

Elements of a recycled aluminum composition sample was assessed using standard methods. The recycled aluminum composition sampled contained 0.18 wt. % iron, 0.45 wt. % silicon, 0.02 wt. % manganese, 0.001 wt. % chromium, 0.012 wt. % copper, 0.022 wt. % titanium, 0.012 wt. % zinc, 0.59 wt. % magnesium, and <0.05 wt. % each of any other elements with a <0.015 wt. % for the total combination of the any other elements.

### 2. Example 2-Carbon Emission with Different Combination of Low Carbon Ingot and Recycled Content

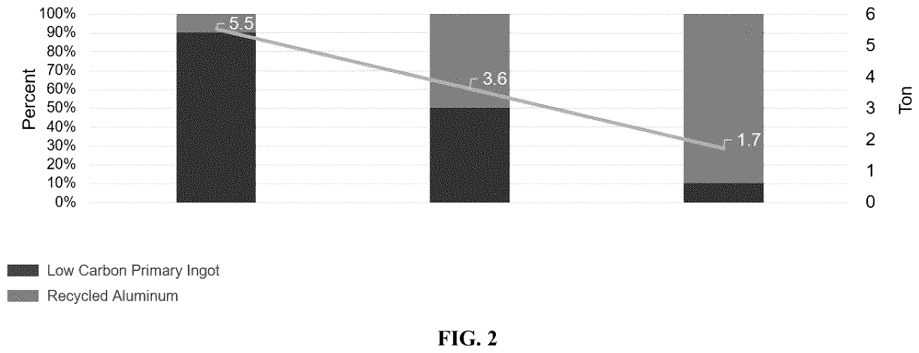

Carbon emissions were calculated when using different proportions of low carbon aluminum and recycled aluminum. There is a significant amount of reduction in carbon emissions upon increasing the recycled content in the composition (see FIG. 2).

Although embodiments of the present application and their advantages have been described in detail, it should be understood that various changes, substitutions and alterations can be made herein without departing from the spirit and scope of the embodiments as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the above disclosure, processes, machines, manufacture, compositions of matter, means, methods, or steps, presently existing or later to be developed that perform substantially the same function or achieve substantially the same result as the corresponding embodiments described herein can be utilized. Accordingly, the appended claims are intended to include within their scope such processes, machines, manufacture, compositions of matter, means, methods, or steps.

1. A recycled aluminum composition comprising:
10 to 90 wt. % primary aluminum; and
10 to 90 wt. % pre-consumer recycled aluminum 6063.

2. The recycled aluminum composition of claim 1, wherein the primary aluminum comprises low carbon primary aluminum.

3. The recycled aluminum composition of claim 1, further comprising post-consumer recycled aluminum.

4. The recycled aluminum composition of claim 3, comprising up to 10 wt. % of the post-consumer recycled aluminum.

5. The recycled aluminum composition of claim 1, comprising:
20 to 30 wt. % of the primary aluminum; and/or
70 to 80 wt. % of the pre-consumer recycled aluminum 6063.

6. The recycled aluminum composition of claim 1, wherein the recycled aluminum composition has:
a tensile strength at break equal to or greater than 205 MPa at 23° C., as measured in accordance with ASTM B557; and/or
a yield strength equal to or greater than 170 MPa at 23° C., as measured in accordance with ASTM B557; and/or
an elongation at break equal to or greater than 8% at 23° C., as measured in accordance with ASTM B557.

7. The recycled aluminum composition of claim 1, wherein the composition comprises silicon and magnesium.

8. The recycled aluminum composition of claim 7, comprising 0.2 to 0.35 wt. % silicon and 0.45 to 0.9 wt. % magnesium.

9. The recycled aluminum composition of claim 1, comprising no more than 0.35 wt. % iron, no more than 0.1 wt. % manganese, no more than 0.1 wt. % chromium, no more than 0.1 wt. % copper, no more than 0.1 wt. % titanium and no more than 0.1 wt. % zinc.

10. The recycled aluminum composition of claim 1, wherein the composition comprises no more than 0.15 wt. % of elements other than aluminum, silicon, magnesium, iron, manganese, chromium, copper, titanium, and zinc.

11. The recycled aluminum composition of claim 1, wherein the composition is an extruded, cast, rolled, or forged composition.

12. A computer chassis, monitor chassis, and/or computer peripheral chassis comprising the recycled aluminum composition of claim 1.

13. The computer chassis, monitor chassis, and/or computer peripheral chassis of claim 12, wherein the computer chassis is a desktop computer chassis, a laptop computer chassis, or a computer tablet chassis.

14. The computer chassis, monitor chassis, and/or computer peripheral chassis of claim 12, wherein at least 10 wt. % of the computer chassis comprises the recycled aluminum composition.

15. A method of making a computer chassis, monitor chassis, and/or computer peripheral chassis, the method comprising forming at least a portion of the computer chassis with the recycled aluminum composition of claim 1.

16. The method of claim 15, wherein at least 70 wt. % of the single part of a computer chassis comprises the recycled aluminum composition.

17. The method of claim 15, wherein the recycled aluminum composition comprises:
20 to 30 wt. % of the primary aluminum; and/or
70 to 80 wt. % of the pre-consumer recycled aluminum 6063.

18. The method of claim 15, wherein the recycled aluminum composition further comprises post-consumer recycled aluminum.

19. A method of making a recycled aluminum of claim 1, the method comprising:
combining a low carbon primary aluminum with a pre-consumer recycled aluminum 6063; and
alloying the low carbon primary aluminum and pre-consumer recycled aluminum 6063 to form the recycled aluminum.

20. The method of claim 19, further comprising conversion and fabrication of the recycled aluminum.
